(19) United States
(12) Patent Application Publication
(10) Pub. No.: US 2026/0114217 A1
(43) Pub. Date: Apr. 23, 2026

(54) APPARATUS FOR BONDING SUBSTRATE

(71) Applicant: SAMSUNG ELECTRONICS CO., LTD., Suwon-si (KR)

(72) Inventor: Inhwa BAEK, Suwon-si (KR)

(73) Assignee: SAMSUNG ELECTRONICS CO., LTD., Suwon-si (KR)

(21) Appl. No.: 19/065,452

(22) Filed: Feb. 27, 2025

(30) Foreign Application Priority Data
Oct. 17, 2024 (KR) 10-2024-0141719

(51) Int. Cl. H01L 21/67; H01L 21/683; H01L 21/687

(52) U.S. Cl. CPC H10P 72/0428; H10P 72/0606; H10P 72/7624; H10P 72/78

(57) ABSTRACT

An apparatus for bonding a substrate includes: a bonding chuck including a base having the substrate on one surface; at least one vacuum region, on one surface of the bonding chuck, configured to provide a vacuum pressure for vacuum-absorbing the substrate; a plurality of first sensors on the one surface of the base; and at least one second sensor on an outer region of the base, wherein the plurality of first sensors are configured to measure a first distance from the plurality of first sensors to one surface of the substrate, and wherein the at least one second sensor is configured to measure a second distance from the at least one second sensor to one surface of the substrate.

### CROSS-REFERENCE TO RELATED APPLICATION

This application claims is based on and claims priority under 35 U.S.C. § 119 to Korean Patent Application No. 10-2024-0141719, filed on Oct. 17, 2024, in the Korean Intellectual Property Office, the disclosure of which is incorporated by reference in its entirety.

### BACKGROUND

The present disclosure relates to a substrate bonding apparatus capable of improving the reliability of a substrate bonding process.

In the manufacturing process of semiconductor devices, a substrate bonding process may be performed to bond a plurality of substrates to each other. This substrate bonding process may be performed to improve the mounting density of semiconductor chips in semiconductor devices. For example, a semiconductor module having a structure in which semiconductor chips are stacked may be advantageous in terms of increasing the mounting density of semiconductor chips, shortening the wiring length between semiconductor chips, and high-speed signal processing. The substrate bonding process may be performed in a wafer-to-wafer scheme in which two wafers are directly bonded without a separate medium. In order to prevent defects in the wafer-to-wafer scheme, it is important to align the substrates being bonded.

The above-described information is intended to enhance understanding of the background of the present disclosure and may include information that does not constitute prior art.

### SUMMARY

The present disclosure solves the above technical problems, and aspects of embodiments of the present disclosure are to provide a substrate bonding apparatus capable of improving the reliability of a substrate bonding process.

The present disclosure solves the above technical problems, and aspects of embodiments of the present disclosure are to provide a substrate bonding apparatus capable of accurately aligning a substrate during a bonding process.

The problems to be solved by the present disclosure are not limited to those described above, and other problems not mentioned may be clearly understood by those skilled in the art from the description of the present disclosure below.

According to an aspect of the disclosure, an apparatus for bonding a substrate includes: a bonding chuck including a base having the substrate on one surface; at least one vacuum region, on one surface of the bonding chuck, configured to provide a vacuum pressure for vacuum-absorbing the substrate; a plurality of first sensors on the one surface of the base; and at least one second sensor on an outer region of the base, wherein the plurality of first sensors are configured to measure a first distance from the plurality of first sensors to one surface of the substrate, and wherein the at least one second sensor is configured to measure a second distance from the at least one second sensor to one surface of the substrate.

According to an aspect of the disclosure, an apparatus for bonding a substrate includes: a first bonding chuck including a base having a first substrate on a lower surface; a second bonding chuck having a second substrate on an upper surface; at least one first vacuum region, on the lower surface of the first bonding chuck, configured to provide a vacuum pressure for vacuum-absorbing the first substrate; a plurality of first sensors on the lower surface of the base of the first bonding chuck; and at least one second sensor on an outer region of the base of the first bonding chuck, wherein the plurality of first sensors are configured to measure a first distance from the plurality of first sensors to one surface of the first substrate, and wherein the at least one second sensor is configured to measure a second distance from the at least one second sensor to one surface of the first substrate.

According to an aspect of the disclosure, an apparatus for bonding a substrate includes: a first bonding chuck including a base having a first substrate on a lower surface; a second bonding chuck having a second substrate on an upper surface; at least one vacuum region configured to provide vacuum pressure for vacuum-absorbing the first substrate, and to penetrate the first bonding chuck; a plurality of first sensors on the lower surface of the base of the first bonding chuck; at least one second sensor on an outer region of the base of the first bonding chuck; and a plurality of sensor lines for connecting the plurality of first sensors to a controller outside the first bonding chuck, wherein the plurality of first sensors are configured to measure a first distance from the plurality of first sensors to one surface of the first substrate, wherein the at least one second sensor is configured to measure a second distance from the at least one second sensor to one surface of the first substrate, wherein the plurality of sensor lines penetrate a side surface of the first bonding chuck to be connected to the controller, wherein the first bonding chuck is divided by a plurality of straight lines passing through a center of the first bonding chuck, and the plurality of first sensors and the at least one second sensor are disposed along each of the plurality of straight lines, wherein the at least one vacuum region includes a first vacuum region on the first bonding chuck, and a second vacuum region further from the center of the first bonding chuck than the first vacuum region, and wherein the plurality of first sensors are installed on at least one of a first position adjacent to an inner side of the first vacuum region or a second position between the first vacuum region and the second vacuum region.

The effects that may be obtained through the present disclosure are not limited to those described above. Any technical effects not mentioned will be clearly understood by those skilled in the art from the description of the present disclosure set forth below.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a cross-sectional view of a substrate bonding apparatus according to some embodiments of the present disclosure;

FIG. 2 illustrates a cross-sectional view of a substrate bonding apparatus according to some embodiments of the present disclosure;

FIG. 3 illustrates one surface of a bonding chuck according to some embodiments of the present disclosure;

FIG. 4 illustrates one surface of a bonding chuck according to some embodiments of the present disclosure;

FIG. 5 illustrates one surface of a first base according to some embodiments of the present disclosure;

FIG. 6 illustrates one surface of a second base according to some embodiments of the present disclosure;

FIG. 7 illustrates an example of a substrate bonding method according to some embodiments of the present disclosure.

FIGS. 8 to 11 illustrate cross-sectional views of example substrate bonding methods using a substrate bonding apparatus according to some embodiments of the present disclosure.

FIG. 12 illustrates a cross-sectional view of an example of a substrate bonding apparatus in which a substrate bonding method according to some embodiments of the present disclosure is performed.

FIG. 13 illustrates a cross-sectional view of an example of a substrate bonding apparatus according to some embodiments of the present disclosure.

### DETAILED DESCRIPTION

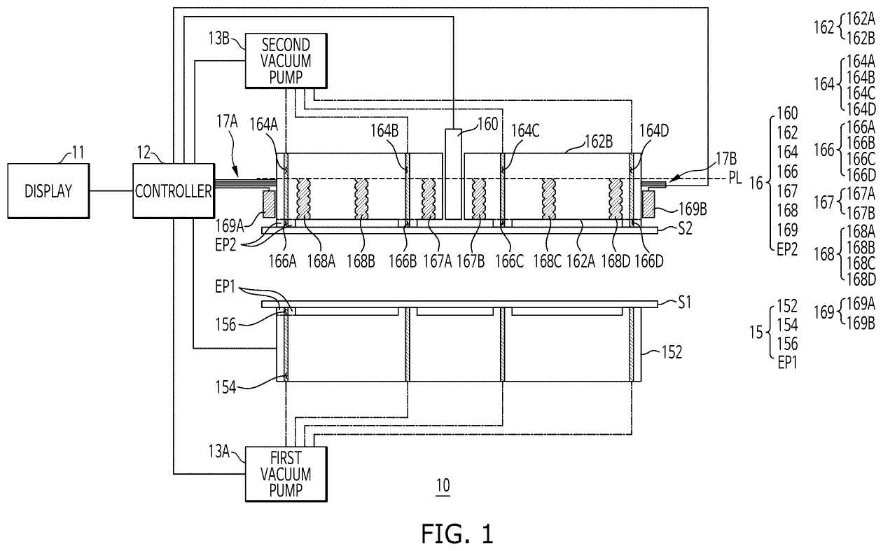

Hereinafter, one or more embodiments of the present disclosure will be described with reference to FIGS. 1 to 13. Identical reference numerals refer to identical components throughout the present disclosure.

FIG. 1 illustrates a cross-sectional view of a substrate bonding apparatus 10 according to some embodiments of the present disclosure. FIG. 1 is an example cross-sectional view showing a structure of a substrate bonding apparatus 10 having a roughly cylindrical shape which is cut in the height direction along a line which crosses the center of the substrate bonding apparatus 10.

Referring to FIG. 1, the substrate bonding apparatus 10 may include a display 11, a controller (a controller) 12, a first vacuum pump 13A, a second vacuum pump 13B, a first bonding chuck 15, a second bonding chuck 16, and a plurality of sensor lines 17A and 17B.

The first bonding chuck 15 may be a lower bonding chuck, and the second bonding chuck 16 may be an upper bonding chuck. However, the embodiment is not limited to this example. For example, the first bonding chuck 15 may be an upper bonding chuck, and the second bonding chuck 16 may be a lower bonding chuck. Hereinafter, the upper side in the Z-axis direction may be referred to as “upper portion”, “upper surface”, “upper side”, etc., and the lower side in the Z-axis direction may be referred to as “lower portion”, “lower surface”, “lower side”, etc. However, relative terms such as “upper portion”, “upper surface” and “upper side”, etc. may be used to describe relationships between components illustrated in the views, and the present disclosure is not limited by such terms.

A first substrate S1 may be disposed on the upper surface of the first bonding chuck 15. In some embodiments, a second substrate S2 may be disposed on the lower surface of the second bonding chuck 16. The first bonding chuck 15 and the second bonding chuck 16 may be disposed to face each other, and the first substrate S1 and the second substrate S2 may face each other.

The first bonding chuck 15 may include a base 152 of the first bonding chuck, at least one vacuum hole 154, a first vacuum region 156, and a first protrusion EP1. The first substrate S1 may be disposed on the upper surface of the base 152 of the first bonding chuck. Specifically, a first protrusion EP1 may be formed on the upper surface of the base 152 of the first bonding chuck. The first protrusion EP1 may be formed by dividing the first vacuum region 156. The first substrate S1 may be disposed on the first protrusion EP1.

Each of at least one first vacuum hole 154 may be connected to at least one first vacuum region 156 and may be connected to a first vacuum pump 13A. The first vacuum pump 13A may form a “vacuum” in at least one first vacuum region 156 connected to each first vacuum hole 154 through at least one first vacuum hole 154. In the present disclosure, “vacuum” may mean a state without gas or a state with almost no gas, and a state where the pressure is 0 or close to 0. As such, at least one first vacuum region 156 may provide a vacuum pressure for adsorbing a first substrate S1 disposed on the first vacuum region 156. The first substrate S1 may be fixed or supported on the first bonding chuck 15 by vacuum pressure. However, the embodiment is not limited to this example. In some embodiments, the first substrate S1 may be fixed or supported on the first bonding chuck 15 through electrostatic force, external force according to Bernoulli's law, etc.

FIG. 1 illustrates that one first vacuum pump 13A is used to form a vacuum in at least one first vacuum region 156, but the embodiment is not limited to this example. For example, a plurality of vacuum pumps may be used to form a vacuum in each of at least one first vacuum region 156.

The second bonding chuck 16 may include a pressurizer 160, a base 162 of the second bonding chuck, at least one second vacuum hole 164, a second vacuum region 166, a second protrusion EP2, and a plurality of sensors 167, 168 and 169. The second substrate S2 may be disposed on the upper surface of the base 162 of the second bonding chuck. Specifically, a second protrusion EP2 may be formed on the upper surface of the base 162 of the second bonding chuck. The second protrusion EP2 may be formed by dividing the second vacuum region 166. The second substrate S2 may be disposed on the second protrusion EP2.

In one embodiment, the base 162 of the second bonding chuck may be removably or detachably coupled to the first base 162A and the second base 162B. A second substrate S2 may be disposed on the lower surface of the first base 162A, and a second base 162B may be disposed on the upper surface of the first base 162A. Referring to FIG. 1, the first base 162A and the second base 162B may be coupled or separated based on the coupling line PL. Because the first base 162A and the second base 162B are detachable, it may be easy to combine, separate, or replace the components included inside the base 162 of the second bonding chuck. For example, a plurality of sensor lines 17A and 17B and a plurality of sensors 167, 168 and 169, etc., may be inserted and installed into the base 162 of the second bonding chuck while the first base 162A and the second base 162B are separated, and then the first base 162A and the second base 162B may be combined.

In one embodiment, the first base 162A may include a plurality of sensor insertion holes penetrating the first base 162A. Each of the plurality of first sensors 167 and 168 may be inserted into each of the plurality of sensor insertion holes. For example, each of first sensors 167 and 168 may be inserted into each of sensor insertion holes through the upper surface of a first base 162A separated from a second base 162B.

In one embodiment, the first sensors 167 and 168 may be screw-fastened to the sensor insertion hole by including a threaded structure. In some embodiments, the first sensors 167 and 168 may be disengaged by a screwing scheme and replaced with another sensor. In some embodiments, the first sensors 167 and 168 may include an O-ring structure to increase binding force.

The pressurizer 160 may be inserted into the central portion of the second bonding chuck 16 so as to be movable in the vertical direction of the second bonding chuck 16 (e.g., in the Z-axis direction). The pressurizer 160 may be configured to be capable of reciprocating in a vertical direction (e.g., in the Z-axis direction) of the second substrate S2 with respect to the second substrate S2. For example, the pressurizer 160 may include an actuator capable of performing an up-and-down reciprocating motion. For example, the actuator may include a multilayer piezoelectric actuator, a voice coil motor, a rack and pinion coupled to a motor, etc.

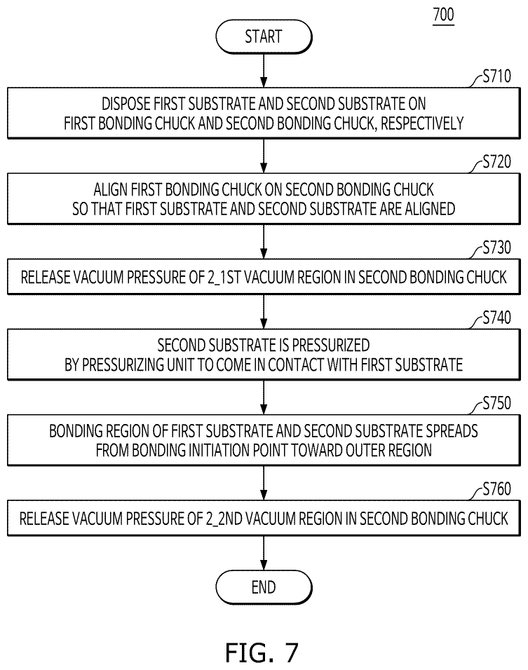

The pressurizer 160 may pressurize the second substrate S2 to change the external shape of the second substrate S2. For example, in a state in which the pressurizer 160 presses the second substrate S2, at least a part of the second substrate S2 may be bent. At least a portion of the modified second substrate S2 may be in contact with the first substrate S1. As the pressurizer 160 applies pressure and the vacuum pressure of the second vacuum region 166 is released, the second substrate S2 may come into contact with the first substrate S1. Accordingly, the second substrate S2 may be bonded to the first substrate S1, thereby forming a bonded substrate. The substrate bonding method is described in detail with reference to FIGS. 7 to 11.

Each of at least one second vacuum hole 164 may be connected to at least one second vacuum region 166 and may be connected to a second vacuum pump 13B. For example, each of the 2_1st vacuum hole 164A and the 2_2nd vacuum hole 164D may be connected to at least a portion of 2_2nd vacuum regions 166A and 166D, and each of the 2_3rd vacuum hole 164B and the 2_4th vacuum hole 164C may be connected to at least a portion of 2_1st vacuum regions 166B and 166C. The second vacuum pump 13B may form a vacuum in at least one second vacuum region 166 connected to each second vacuum hole 164 through at least one second vacuum hole 164. As such, at least one second vacuum region 166 may provide vacuum pressure for adsorbing a second substrate S2 disposed on the second vacuum region 166. The second substrate S2 may be fixed or supported on the second bonding chuck 16 by vacuum pressure. However, the embodiment is not limited to this example. In some embodiments, the second substrate S2 may be fixed or supported on the second bonding chuck 16 through electrostatic force, external force according to Bernoulli's law, etc.

FIG. 1 illustrates that one second vacuum pump 13B is used to form a vacuum in at least one second vacuum region 166, but the embodiment is not limited to this example. For example, a plurality of vacuum pumps may be used to form a vacuum in each of at least one second vacuum region 166.

A plurality of sensors 167, 168 and 169 may measure the distance from each of the plurality of sensors to the upper surface of the second substrate S2. Here, the upper surface of the second substrate S2 may face the lower surface of the second bonding chuck 16. For example, the plurality of sensors 167, 168 and 169 may include a laser distance sensor, a light source, and an image sensor.

The plurality of sensors 167, 168, and 169 may include a plurality of first sensors 167 and 168 and at least one second sensor 169. The plurality of first sensors 167 and 168 may be disposed on the lower surface of the base 162 of the second bonding chuck. In some embodiments, at least one second sensor 169 may be disposed on an outer region of the base 162 of the second bonding chuck. The outer region of the base 162 of the second bonding chuck may include an outer peripheral region of the base 162 of the second bonding chuck. For example, the outer region of the base 162 of the second bonding chuck may include a region next to the outer surface of the base 162 of the second bonding chuck.

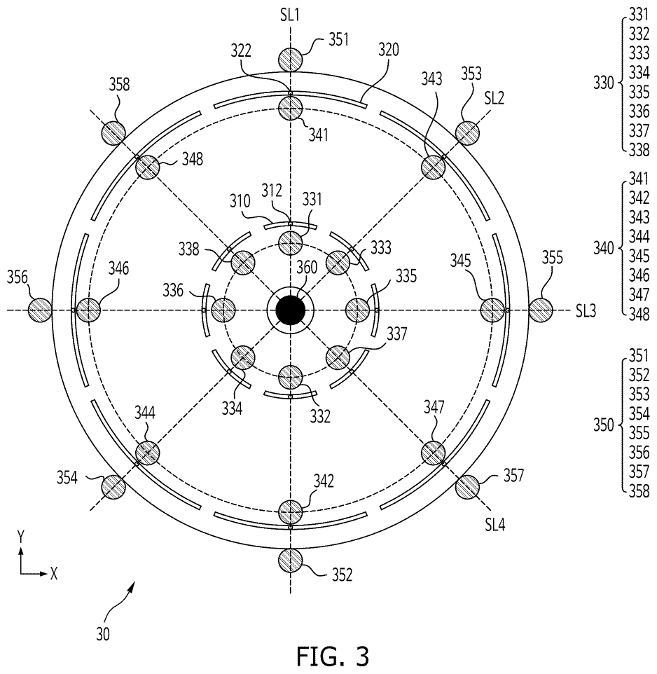

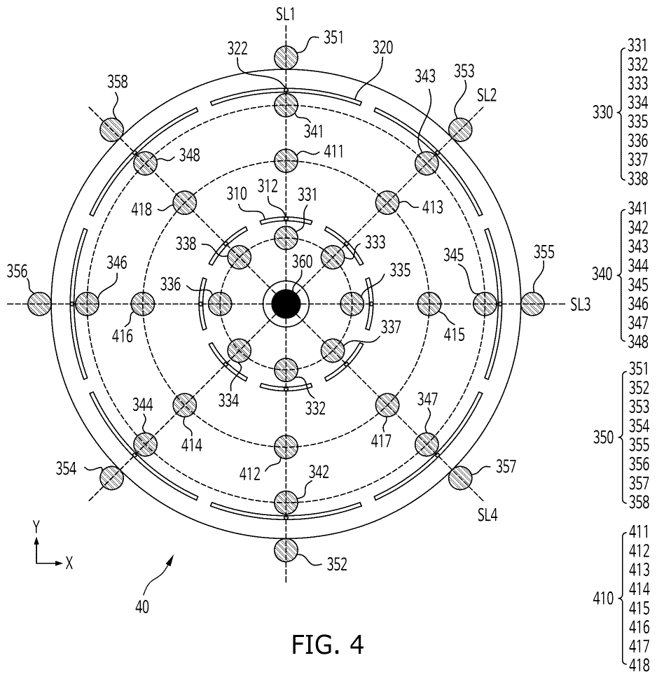

In one embodiment, at least one second vacuum region 166 may include a 2_1st vacuum regions 166B and 166C formed on the lower surface of the second bonding chuck 16. In some embodiments, at least one vacuum region 166 may further include a 2_2nd vacuum regions 166A and 166D formed further from the center of the second bonding chuck 16 on the lower surface of the second bonding chuck 16 than the 2_1st vacuum regions 166B and 166C. Each of the 2_1st vacuum regions 166B and 166C and the 2_2nd vacuum regions 166A and 166D may be composed of one region or may be composed of a plurality of regions. The specific structures of the 2_1st vacuum regions 166B and 166C and the 2_2nd vacuum regions 166A and 166D are described in detail with reference to FIGS. 3 and 4.

In one embodiment, a plurality of first sensors 167 and 168 may be disposed in an array on the lower surface of the second bonding chuck 16. The plurality of first sensors 167 and 168 may include at least one of a third sensor 167 and a fourth sensor 168. The third sensor 167 may be installed at a location adjacent to the inside of the 2_1st vacuum regions 166B and 166C. The fourth sensor 168 may be installed between the 2_1st vacuum regions 166B and 166C and the 2_2nd vacuum regions 166A and 166D. For example, the fourth sensor 168 may include fifth sensors 168A and 168D and sixth sensors 168B and 168C. The fifth sensors 168A and 168D may be installed at a location adjacent to the inside of the 2_2nd vacuum regions 166A and 166D. As another example, the sixth sensors 168B and 168C may be disposed at an intermediate position between the 2_1st vacuum regions 166B and 166C and the 2_2nd vacuum regions 166A and 166D. That is, the plurality of first sensors 167 and 168 may be disposed on at least one of a position adjacent to the inside of the 2_1st vacuum regions 166B and 166C, an intermediate position between the 2_1st vacuum regions 166B and 166C and the 2_2nd vacuum regions 166A and 166D, and a position adjacent to the inside of the 2_2nd vacuum regions 166A and 166D. However, these sensor locations are only example, the embodiment is not limited to these examples.

In one embodiment, the third sensor 167 may be configured in a plurality of numbers. In this case, a 3_1st sensor 167A and a 3_2nd sensor 167B may be disposed symmetrically with respect to the center of the second bonding chuck 16. Similarly, the fourth sensor 168 may be configured in a plurality of units. In this case, one 1_2nd sensor 168A and another 1_2nd sensor 168D may be disposed symmetrically with respect to the center of the second bonding chuck 16. The arrangement of a plurality of first sensors 167 and 168 and at least one second sensor 169 on the lower surface of the second bonding chuck 16 is described in detail with reference to FIGS. 3 and 4.

The controller 12 may control the first bonding chuck 15, the second bonding chuck 16, the first vacuum pump 13A, and the second vacuum pump 13B so that the first substrate S1 and the second substrate S2 are aligned. For example, the controller 12 may operate the first vacuum pump 13A to fix or support the first substrate S1 on the first bonding chuck 15. Similarly, the controller 12 may operate the second vacuum pump 13B to fix or support the second substrate S2 on the second bonding chuck 16. The controller 12 may control the first bonding chuck 15 and the second bonding chuck 16 so that the first substrate S1 and the second substrate S2 are aligned to face each other. The controller 12 may control the operation of the pressurizer 160 and the second vacuum pump 13B to separate the second substrate S2 from the second bonding chuck 16.

The controller 12 may be implemented in hardware, firmware, software, or any combination thereof. For example, the controller 12 may include a computing device such as a workstation computer, a desktop computer, a laptop computer, or a tablet computer. The controller 12 may include a simple controller, a complex processor such as a microprocessor, a CPU or a GPU, a processor configured by software, dedicated hardware, or firmware. The controller 12 may be implemented by, for example, a general-purpose computer or application-specific hardware such as a digital signal processor (DSP), field programmable gate array (FPGA), and an application specific integrated circuit (ASIC). The controller 12 may be implemented as instructions stored on a machine-readable medium that may be read and executed by one or more processors. Here, a machine-readable medium may include any mechanism for storing and/or transmitting information in a form readable by a machine e.g., (a computing device). For example, the machine-readable medium may include read only memory (ROM), random access memory (RAM), magnetic disk storage media, optical storage media, flash memory devices, electrical, optical, acoustical or other forms of radio signals (e.g., carrier waves, infrared signals, digital signals, etc., and any other signals).

In some embodiments, the controller 12 may control a plurality of sensors 167, 168 and 169, a first vacuum region 156, and a second vacuum region 166. Specifically, distance data generated by measurement by the plurality of sensors 167, 168 and 169 may be received from the plurality of sensors 167, 168 and 169. For example, the controller 12 may receive distance data through a plurality of sensor lines 17A and 17B that connect the controller 12 to the plurality of sensors 167, 168 and 169. Here, the distance data may be data measuring the distance from each of the plurality of sensors 167, 168 and 169 to one surface of the second substrate S2.

In one embodiment, the substrate bonding apparatus 10 may include a plurality of sensor lines 17A and 17B connecting the plurality of sensors 167, 168 and 169 to the controller 12. For example, the plurality of sensor lines 17A and 17B may include a sensor line connected to at least one second sensor 169 and a controller 12 disposed in an outer region of the base 162 of the second bonding chuck. The plurality of sensor lines 17A and 17B may include a first sensor line set 17A and a second sensor line set 17B including a plurality of first sensors 167 and 168 inserted into the base 162 of the second bonding chuck.

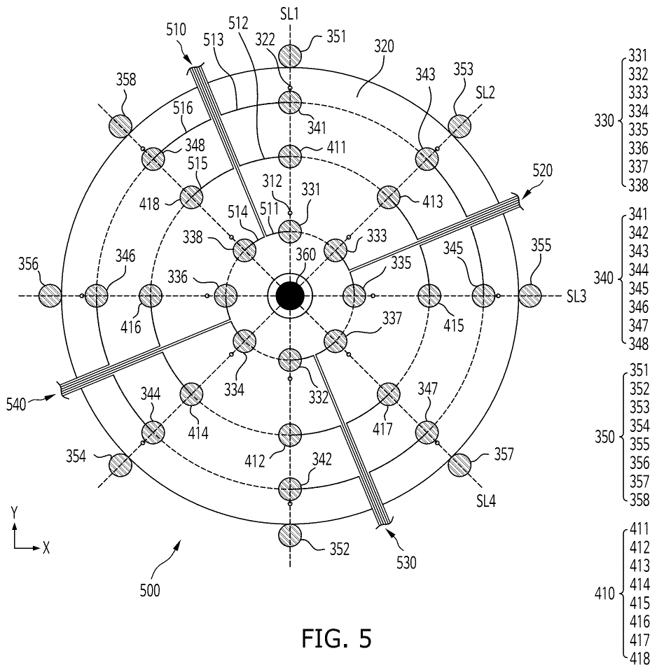

In one embodiment, the first sensor line set 17A and the second sensor line set 17B may be disposed to penetrate the side surface of the second bonding chuck 16. That is, the first sensor line set 17A and the second sensor line set 17B may not pass through the upper surface of the second bonding chuck 16. Specifically, the first sensor line set 17A and the second sensor line set 17B may be disposed to penetrate the side surface of the first base 162A among the bases 162 of the second bonding chuck. The first base 162A may include at least one mounting groove in which the first sensor line set 17A and the second sensor line set 17B are mounted and exiting through the side surface of the second bonding chuck 16. The structure of the mounting groove and the plurality of sensor lines in the second bonding chuck 16 is described in detail with reference to FIG. 5.

In one embodiment, the controller 12 may control the vacuum pressure of the first vacuum region 156 and/or the second vacuum region 166 by controlling the first vacuum pump 13A and/or the second vacuum pump 13B based on the distance data. For example, a 3_1st sensor 167A and a 3_2nd sensor 167B may be disposed symmetrically with respect to the center of the second bonding chuck 16. The distance measured by the 3_1st sensor 167A and the distance measured by another 3_2nd sensor 167B may be different from each other due to the second substrate S2 being unevenly disposed on the second bonding chuck 16, etc. In this case, the controller 12 may control the vacuum pressure for a part of the second vacuum region 166B adjacent to the 3_1st sensor 167A. In some embodiments, the controller 12 may regulate the vacuum pressure for another portion 166C of the second vacuum region adjacent to the 3_2nd sensor 167B.

In one embodiment, the controller 12 may adjust the pressure which the pressurizer 160 applies to the second substrate S2, based on the distance data. For example, the controller 12 may adjust the pressure applied by the pressurizer 160 to the second substrate S2 based on distance data by considering the thickness of the first substrate S1, the thickness of the second substrate S2, and the distance between the first substrate S1 and the second substrate S2. The controller 12 may adjust the pressure of the pressurizer 160 to an appropriate pressure to form a bonded substrate in which the first substrate S1 and the second substrate S2 are bonded.

In one embodiment, the controller 12 may be operated to generate a warning message in a state in which the distance data deviates from a predetermined threshold. For example, a 3_1st sensor 167A and a 3_2nd sensor 167B may be disposed symmetrically with respect to the center of the second bonding chuck 16. The difference between the distance measured by the 3_1st sensor 167A and the distance measured by another 3_2nd sensor 167B may deviate from a predetermined threshold due to the second substrate S2 being disposed on the second bonding chuck 16 in an unbalanced manner, etc. In this case, the controller 12 may generate a warning message. For example, the controller 120 may visually output information, which indicates that the distance data has exceeded a predetermined reference value, to the display 11. As another example, the controller 120 may output an alarm associated with a warning message through an audio output device or the like. However, the embodiment is not limited to this example. In some embodiments, the controller 120 may output information associated with the warning message using an output device included in or connected to the substrate bonding apparatus 10. In some embodiments, the controller 120 may stop the operation performed in the substrate bonding apparatus 10 along with the output of a warning message.

The display 11 may refer to any display device associated with the substrate bonding apparatus 10, for example, any display device that is controlled by the substrate bonding apparatus 10 or capable of displaying any information/data provided from the substrate bonding apparatus 10.

In one embodiment, the display 11 may display distance data received by the controller 12. For example, the display 11 may display an upper surface image of the second substrate S2 and display the positions of a plurality of sensors 167, 168 and 169 on the upper surface image. The display 11 may display distance data measured by each of the plurality of sensors 167, 168 and 169. This allows the user to intuitively identify the location of the second substrate S2. For example, the user may determine the detailed positional relationship between a partial region of the second substrate S2 and a partial region of the second bonding chuck 16 while the second substrate S2 is separated from the second bonding chuck 16 and bonded to the first substrate S1.

FIG. 1 illustrates that the plurality of sensors are disposed on the base 152 of the first bonding chuck, but the embodiment is not limited to this example. Similarly to the plurality of sensors 167, 168 and 169 disposed on the second bonding chuck 16, a plurality of sensors may also be disposed on the base 152 of the first bonding chuck. Each of the plurality of sensors measures the distance from each of the plurality of sensors to the bottom surface of the first substrate S1 to generate distance data, and the controller 12 may receive the distance data. The controller 12 may control some configurations of the substrate bonding apparatus 10 based on the corresponding distance data.

As described above, the position of the second substrate S2 may be easily identified based on distance data measured and generated by a plurality of sensors 167, 168 and 169. For example, the presence or absence of a foreign substance, etc., disposed on the upper surface of the second substrate S2 may be determined based on distance data. As another example, in order for the second substrate S2 to be bonded to the first substrate S1, at least a portion of the second substrate S2 may be separated from the second bonding chuck 16. At least a portion of the separated second substrate S2 may be bonded to the first substrate S1 to form a bonding region. The controller 12 may control the point of time at which a portion of the second substrate S2 is separated from the second bonding chuck 16 by controlling the vacuum pumps 13A and 13B, the pressurizer 160, etc. based on the distance data. The bonding region may be formed so as to be symmetrical in the diameter direction (e.g., the diameter direction of the XY plane) of the bonded surface (e.g., one surface where the first substrate S1 and the second substrate S2 are in contact and bonded), thereby improving the quality of the bonded substrate. That is, the reliability of the substrate bonding process may be improved.

In some embodiments, the position of the edge region of the second substrate S2 may be identified using at least one second sensor 169 disposed on the outer region of the base 162 of the second bonding chuck. As such, the point in time when the outer region and the edge region of the second substrate S2 are separated from the second bonding chuck 16 (e.g., the point in time of free fall) may be specifically identified.

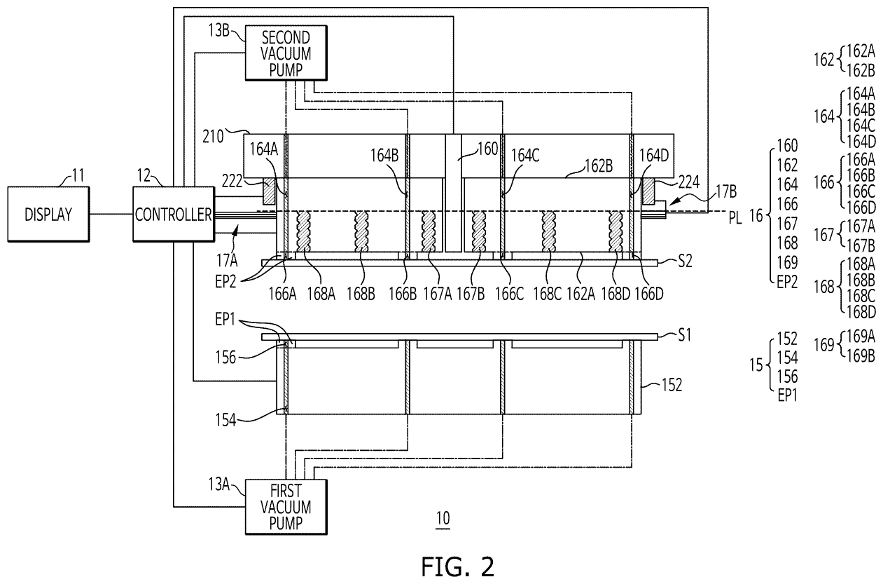

FIG. 2 illustrates a cross-sectional view of a substrate bonding apparatus 20 according to some embodiments of the present disclosure. FIG. 2 illustrates a cross-sectional view of a substrate bonding apparatus 20 having a roughly cylindrical shape which is cut in the height direction along a line which crosses the center of the substrate bonding apparatus 20.

Referring to FIG. 2, the substrate bonding apparatus 20 may include a display 11, a controller 12, a first vacuum pump 13A, a second vacuum pump 13B, a first bonding chuck 15, a second bonding chuck 16, a plurality of sensor lines 17A and 17B, a plate 210, and at least one second sensor 222 and 224.

The substrate bonding apparatus 20 (to be described later with respect to FIG. 2) may include second sensors 222 and 224 disposed at different positions from the position of the second sensor 169 of the substrate bonding apparatus 10 described with reference to FIG. 1. In some embodiments, the substrate bonding apparatus 20 of FIG. 2 may further include a plate 210 disposed on the base 162 of the second bonding chuck in the substrate bonding apparatus 10 of FIG. 1. In FIG. 2, the differences from the substrate bonding apparatus 10 described with reference to FIG. 1 are mainly explained.

In one embodiment, the plate 210 may be disposed on the upper surface of the base 162 of the second bonding chuck. For example, the plate 210 may be a physical structure on which the second bonding chuck 16 is supported. The plate 210 may have various shapes without affecting the configuration included in the second bonding chuck 16. For example, in order not to interfere with the operation of the pressurizer 160, the plate 210 may have a through hole formed in the center. The plate 210 may be formed such that the vacuum hole 164 extends into the inside of the plate 210 for connection between the vacuum hole 164 and the second vacuum pump 13B.

In one embodiment, at least one second sensor 222 and 224 may be mounted on the plate 210. For example, the diameter of the plate 210 may be larger than the diameter of the base 162 of the second bonding chuck. In this case, a portion of the lower surface of the plate 210 may be exposed from the second bonding chuck 16. At this time, one or more second sensors 222 and 224 may be disposed on the lower surface of the exposed plate 210. However, the embodiment is not limited to this example. In some embodiments, in a state in which the second sensors 222 and 224 are located at positions where the second sensors 222 and 224 may sense the upper surface of the second substrate S2, the second sensors 222 and 224 may be mounted on the plate 210.

FIG. 3 illustrates one surface of a bonding chuck 30 according to some embodiments of the present disclosure. One surface of the bonding chuck 30 may correspond to the lower surface of the second bonding chuck 16 described with reference to FIG. 1. For example, the bonding chuck 30 may include a plurality of sensors 330, 340 and 350 of the second bonding chuck 16 described with reference to FIG. 1. In FIG. 3, the arrangement of a plurality of sensors 330, 340 and 350 on one surface of a bonding chuck is mainly described.

Referring to FIG. 3, in one embodiment, the bonding chuck 30 may include a pressurizer 360 inserted through the central portion of the bonding chuck 30. The bonding chuck 30 may include a first vacuum region 310 having a ring shape around the pressurizer 360. Similarly, the bonding chuck 30 may include a second vacuum region 320 having a ring shape around the pressurizer 360. The second vacuum region 320 may be formed further from the center of the bonding chuck 30 than the first vacuum region 310. Each of the first vacuum region 310 and the second vacuum region 320 may be divided by a protrusion formed on one surface of the bonding chuck 30. The first vacuum region 310 and/or the second vacuum region 320 may provide vacuum pressure for vacuum-absorbing a substrate disposed on one surface of the bonding chuck 30. For example, the first vacuum region 310 may correspond to the 2_1st vacuum regions 166B and 166C of FIG. 1, and the second vacuum region 320 may correspond to the 2_2nd vacuum regions 166A and 166D of FIG. 1.

In one embodiment, the first vacuum region 310 may include a plurality of first vacuum regions 310. For example, each of the plurality of first vacuum regions 310 may have an arc shape. Each of the plurality of first vacuum regions 310 may have a substantially equal distance from the pressurizer 160. Similarly, the second vacuum region 320 may include a plurality of second vacuum regions 320. For example, each of the plurality of second vacuum regions 320 may have an arc shape. Each of the plurality of second vacuum regions 320 may have a substantially equal distance from the pressurizer 160.

Each of the plurality of first vacuum regions 310 may include a first vacuum hole 312 penetrating the bonding chuck to provide vacuum pressure. Each of the plurality of first vacuum regions 310 may provide vacuum pressure through a vacuum pump connected to the first vacuum hole 312. Similarly, each of the plurality of second vacuum regions 320 may include a second vacuum hole 322 penetrating the bonding chuck to provide a vacuum pressure. Each of the plurality of second vacuum regions 320 may provide vacuum pressure through a vacuum pump connected to the second vacuum hole 322.

In one embodiment, the bonding chuck 30 may include a plurality of first sensors 330 and 340. A plurality of first sensors 330 and 340 may be disposed on one surface of the bonding chuck 30. For example, some of the plurality of first sensors 330 and 340 may be disposed to have substantially the same distance from the center of the bonding chuck 30.

In one embodiment, the bonding chuck 30 may include at least one second sensor 350. At least one second sensor 350 may be mounted on the outer surface of the base of the bonding chuck 30. For example, at least one second sensor 350 may be disposed at equal intervals along the circumference of the bonding chuck 30. Referring to FIG. 3, each of the 2_1st sensor 351 to the 2_6th sensor 356 may be disposed along the circumference of the bonding chuck 30.

In one embodiment, the plurality of first sensors 330 and 340 may include a plurality of third sensors 330 and a plurality of fourth sensors 340. The plurality of third sensors 330 may include a 3_1st sensor 331 to a 3_8th sensor 338. The plurality of fourth sensors 340 may include a 4_1st sensor 341 to a 4_8th sensor 348. Some of the plurality of first sensors 330 and 340 may be located inside the first vacuum region 310 on one surface of the bonding chuck 30. Referring to FIG. 3, each of the plurality of third sensors 330 may be installed at a position adjacent to the inside of the first vacuum region 310. In some embodiments, other portions of the plurality of first sensors 330 and 340 may be installed at a location between the first vacuum region 310 and the second vacuum region 320. Referring to FIG. 3, each of the plurality of fourth sensors 340 may be installed at a position between the first vacuum region 310 and the second vacuum region 320. Specifically, each of the 4_1st sensor 341 to the 4_8th sensor 348 may be installed at a position adjacent to the inside of the second vacuum region 320.

In one embodiment, one surface of the bonding chuck 30 may be divided by a plurality of straight lines SL1 to SL4 passing through the center of the bonding chuck 30. These plurality of straight lines SL1 to SL4 may be imaginary straight lines established for convenience of explanation. Each of the plurality of first sensors 330 and 340 may be disposed along each of the plurality of straight lines SL1 to SL4, and each of at least one second sensor 350 may be disposed along each of the plurality of straight lines SL1 to SL4.

In one embodiment, a plurality of straight lines SL1 to SL4 may divide one surface of the bonding chuck 30 into a plurality of regions. At this time, two adjacent straight lines among the plurality of straight lines SL1 to SL4 have a constant angle, and the angle between the two adjacent straight lines may be the same for the plurality of straight lines SL1 to SL4. Referring to FIG. 3, a plurality of straight lines SL1 to SL4 divide one surface of the bonding chuck 30 into eight regions, and two adjacent straight lines among the plurality of straight lines SL1 to SL4 may have an angle of about 45 degrees.

Referring to FIG. 3, the 3_1st sensor 331, the 3_2nd sensor 332, the 4_1st sensor 341, the 4_2nd sensor 342, the 2_1st sensor 351, and the 2_2nd sensor 352 may be disposed along the first straight line SL1. At this time, the 3_1st sensor 331 and the 3_2nd sensor 332 may be disposed symmetrically with respect to the center of the bonding chuck 30. In some embodiments, the 4_1st sensor 341 and the 4_2nd sensor 342 may be disposed symmetrically with respect to the center of the bonding chuck 30. The 2_1st sensor 351 and the 2_2nd sensor 352 may be disposed symmetrically with respect to the center of the bonding chuck 30.

Similarly, the 3_3rd sensor 333, the 3_4th sensor 334, the 4_3rd sensor 343, the 4_4th sensor 344, the 2_3rd sensor 353, and the 2_4th sensor 354 may be disposed along the second straight line SL2, the 3_5th sensor 335, the 3_6th sensor 336, the 4_5th sensor 345, the 4_6th sensor 346, the 2_5th sensor 355, and the 2_6th sensor 356 may be disposed along the third straight line SL3, and the 3_7th sensor 337, the 3_8th sensor 338, the 4_7th sensor 347, the 4_8th sensor 348, the 2_7th sensor 357, and the 2_8th sensor 358 may be disposed along the fourth straight line SL4. The first straight line SL1 and the third straight line SL3 are orthogonal to each other, and the second straight line SL2 and the fourth straight line SL4 may be orthogonal to each other. However, the number of straight lines may be more or less than four, and correspondingly, one surface of the bonding chuck 30 may be divided into more or less than eight regions. In some embodiments, the angle between adjacent straight lines among plurality of straight lines may be more or less than 45 degrees.

A plurality of sensors 330, 340 and 350 are disposed along a plurality of straight lines SL1 to SL4 to measure the distance to the substrate. A plurality of sensors 330, 340 and 350 may be disposed radially around the bonding chuck 30 on one surface of the bonding chuck 30. For example, a plurality of sensors 330, 340 and 350 may be symmetrical about the bonding chuck 30 in a diameter direction on one surface of the bonding chuck 30. Based on the distance data measured and generated by the plurality of sensors 330, 340 and 350, the distance between the substrate and the bonding chuck 30 in the radial direction may be specifically determined.

FIG. 4 illustrates one surface of a bonding chuck 40 according to some embodiments of the present disclosure. One surface of the bonding chuck 40 to be described with reference to FIG. 4 may correspond to the lower surface of the second bonding chuck 16 described with reference to FIG. 1.

Referring to FIG. 4, the bonding chuck 40 may further include a plurality of fifth sensors 410, compared to the plurality of sensors 330, 340 and 350 of the bonding chuck 30 described with reference to FIG. 3.

That is, the plurality of sensors 330, 340, 350 and 410 according to the example of FIG. 4 may include a plurality of first sensors 330, 340 and 410. Some of the plurality of first sensors 330, 340 and 410 may be located inside the first vacuum region 310 on one surface of the bonding chuck 40. In some embodiments, some of the other first sensors 330, 340 and 410 may be disposed between the first vacuum region 310 and the second vacuum region 320 on one surface of the bonding chuck 40. Referring to FIG. 4, each of the plurality of fourth sensors 340 may be installed at a position adjacent to the inside of the second vacuum region 320. In some embodiments, each of the plurality of fifth sensors 410 may be installed at an intermediate position between the first vacuum region 310 and the second vacuum region 320.

Referring to FIG. 4, the 5_1st sensor 411 and the 5_2nd sensor 412 may be disposed along the first straight line SL1 together with other sensors. At this time, the 5_1st sensor 411 and the 5_2nd sensor 412 may be disposed symmetrically about the center of the bonding chuck 40. Similarly, the 5_3rd sensor 413 and the 5_4th sensor 414 may be disposed along the second straight line SL2 together with other sensors. The 5_5th sensor 415 and the 5_6th sensor 416 may be disposed along the third straight line SL3 together with other sensors. The 5_7th sensor 417 and the 5_8th sensor 418 may be disposed along the fourth straight line SL4 together with other sensors.

However, the embodiment is not limited to this example. In some embodiments, additional sensors may be further disposed on one surface of the bonding chuck 40. For example, additional sensors may be further disposed in the region between the first vacuum region 310 and the second vacuum region 320 and/or in the inner region of the first vacuum region 310. Further disposed sensors may be disposed along the plurality of straight lines SL1 to SL4.

As described above, by further disposing sensors along the plurality of straight lines SL1 to SL4, the distance between the substrate and the bonding chuck 40 in the radial direction may be more precisely determined.

FIG. 5 illustrates one surface of a first base 500 according to some embodiments of the present disclosure. Another base may be disposed on one surface of the first base 500. At this time, the first base 500 and another base may be combined to form the base of the bonding chuck. For example, one surface of the first base 500 may correspond to the upper surface of the first base 162A described with reference to FIG. 1. Here, a substrate may be disposed on one surface of the first base 500 opposite to the other side of the first base 500.

A pressurizer 360 may be inserted vertically into the center of the first base 500. In some embodiments, one surface of the first base 500 may have a first vacuum hole 312 and a second vacuum hole 322 formed thereon. The first vacuum hole 312 may be connected to a first vacuum region (e.g., the first vacuum region 310 of FIG. 3) formed on the other surface of the first base 500 opposite to one surface of the first base 500, and the second vacuum hole 322 may be connected to a second vacuum region (e.g., the second vacuum region 320 of FIG. 3) formed on the other surface of the first base 500 opposite to one surface of the first base 500.

In one embodiment, one surface of the first base 500 may include a plurality of sensor insertion holes into which a plurality of sensors 330, 340, 350 and 410 are inserted. The plurality of sensor insertion holes may be formed through the first base 500. Referring to FIG. 5, each of the plurality of sensors 330, 340, 350 and 410 may be inserted into a plurality of sensor insertion holes through one surface of the first base 500. However, the embodiment is not limited to this example. In some embodiments, the plurality of sensors 330, 340, 350 and 410 may be inserted through another surface facing one surface of the first base 500.

In one embodiment, the size of the sensor insertion hole may correspond to the size of the sensor or may be larger. For example, the diameter of the sensor insertion hole may be about 2 mm or more, and the diameter of the sensor may be about 2 mm or less. However, the embodiment is not limited to this example.

Each of the plurality of sensors 330, 340, 350 and 410 may include a male screw structure, and the plurality of sensor insertion holes may include a female screw structure corresponding to the screw structure. Each of the plurality of sensors 330, 340, 350 and 410 may be screw-coupled to the plurality of sensor insertion holes.

The sensor may be connected to the controller (e.g., the controller 12 of FIG. 1) via a sensor line. A plurality of sensor lines connected to a plurality of sensors 330, 340, 350 and 410 may penetrate the side surface of the first base 500. For example, the plurality of sensor lines may include a first sensor line set 510, a second sensor line set 520, a third sensor line set 530, and a fourth sensor line set 540. Referring to FIG. 5, each of the first sensor line set 510, the second sensor line set 520, the third sensor line set 530, and the fourth sensor line set 540 may be exiting through different regions of the side surface of the first base 500. For example, each of the first sensor line set 510, the second sensor line set 520, the third sensor line set 530, and the fourth sensor line set 540 may be composed of at least one sensor line. For example, the first sensor line set 510 may include a sensor line 511 connected to the 3_1st sensor 331, a sensor line 512 connected to the 5_1st sensor 411, a sensor line 513 connected to the 4_1st sensor 341, a sensor line 514 connected to the 3_8th sensor 338, a sensor line 515 connected to the 5_8th sensor 418, and a sensor line 516 connected to the 4_8th sensor 348. However, the embodiment is not limited to this example. In some embodiments, the plurality of sensor lines may be composed of sets of less than four or more than four sensor lines and may penetrate the side surface of the first base 500.

Each of the plurality of sensor lines may pass an area next to the first vacuum hole 312 and the second vacuum hole 322 and pass through the side surface of the first base 500. That is, each of the plurality of sensor lines does not cross the first vacuum hole 312 and the second vacuum hole 322, so as not to interfere with the vacuum pressure provided by the first vacuum hole 312 and the second vacuum hole 322. However, the embodiment is not limited to this example. In some embodiments, the plurality of sensor lines may be existing through the side surface of the first base 500 without interfering with other configurations within the first base 500.

In one embodiment, the first base 500 may include at least one mounting groove in which each of the plurality of sensor lines is mounted within the interior of the first base 500. The width of the mounting groove may correspond to the width of a sensor line or a plurality of sensor lines. For example, a mounting groove in which one sensor line is mounted may correspond to one sensor line width, and a mounting groove in which plurality of sensor lines are mounted may correspond to a plurality of sensor line widths. The mounting groove may serve as a passage for each of the plurality of sensors 330, 340, 350 and 410 to penetrate the side surface of the base. Referring to FIG. 5, the mounting groove may extend from each of the plurality of sensors 330, 340, 350 and 410 and may face the side surface of the first base 500. The plurality of sensor lines may be inserted into the mounting groove.

As described above, the plurality of sensor lines are disposed to penetrate the side surface of the bonding chuck, so that the plurality of sensor lines may not interfere with the internal configuration of the bonding chuck or the configuration connected to the bonding chuck. This allows more space to be secured in the bonding chuck to accommodate the configuration, and facilitates connection of the bonding chuck to other configurations.

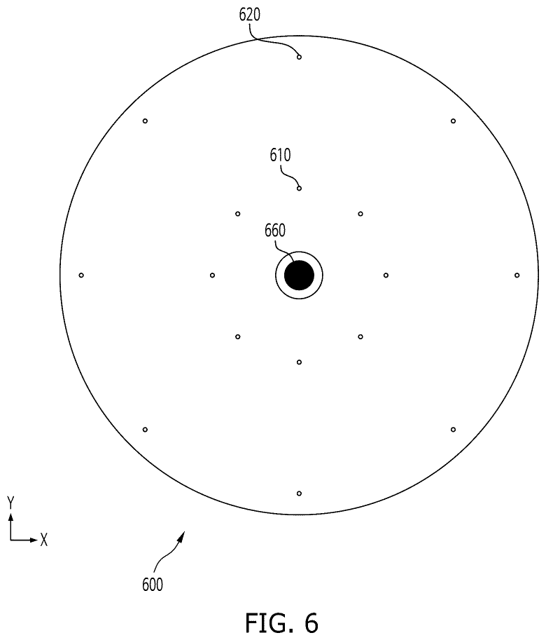

FIG. 6 illustrates one surface of a second base 600 according to some embodiments of the present disclosure.

Referring to FIG. 6, one surface of the second base 600 may be disposed on one surface of another base. For example, one surface of the second base 600 may be disposed on one surface of the first base 500 of FIG. 5. Thereafter, the second base 600 may be combined with another base to form the base of the bonding chuck. Hereinafter, the description is based on the assumption that one surface of the second base 600 is disposed on one surface of the first base 500 and may be attached and detached.

A pressurizer 660 may be inserted vertically into the center of the second base 600. In some embodiments, the second base 600 may include a first vacuum hole 610 and a second vacuum hole 620. The first vacuum hole 610 may be disposed to correspond to the first vacuum hole of the first base. The second vacuum hole 620 may be disposed to correspond to the second vacuum hole of the first base. The vacuum hole of the bonding chuck may be composed of a first vacuum hole 610 of the second base 600 and a first vacuum hole of the first base. In some embodiments, the vacuum hole of the bonding chuck may be composed of a second vacuum hole 620 of the second base 600 and a second vacuum hole of the first base. The vacuum hole of the bonding chuck configured in this way may provide vacuum pressure to the vacuum region.

As described above, the second base 600 may include a first vacuum hole 610, a second vacuum hole 620, and a through hole into which a pressurizer 660 is inserted. The second base 600 may further include additional configurations for operating the substrate bonding apparatus in the remaining region. That is, more space may be secured in the bonding chuck to accommodate the configuration, and the bonding chuck may be easily connected to other configurations.

FIG. 7 illustrates a flowchart 700 about an example of a substrate bonding method according to some embodiments of the present disclosure. The substrate bonding method may be performed by a substrate bonding apparatus 10 described with reference to FIG. 1.

Referring to FIG. 7, the substrate bonding method may be initiated by disposing a first substrate and a second substrate on a first bonding chuck and a second bonding chuck, respectively (S710). Here, the first bonding chuck may be a bonding chuck disposed at the lower portion, and the second bonding chuck may be a bonding chuck disposed at the upper portion. For example, the first substrate may be disposed on the upper surface of the first bonding chuck, and the second substrate may be disposed on the lower surface of the second bonding chuck.

In one embodiment, the first substrate may be secured on the first bonding chuck. For example, the first substrate may be vacuum-absorbed to the first bonding chuck by the vacuum pressure provided by the first vacuum region formed in the first bonding chuck. Similarly, the second substrate may be secured on the second bonding chuck. For example, the second substrate may be vacuum-absorbed to the second bonding chuck by the vacuum pressure provided by the second vacuum region formed in the second bonding chuck.

In one embodiment, the substrate bonding apparatus may align the first bonding chuck on the second bonding chuck so that the first substrate and the second substrate are aligned (S720). Specifically, the upper surface of the first substrate and the lower surface of the second substrate are aligned so that the upper surface of the first substrate and the lower surface of the second substrate may face each other.

In one embodiment, the substrate bonding apparatus may release the vacuum pressure of the 2_1st vacuum region in the second bonding chuck (S730). Accordingly, a portion of the second substrate facing the 2_1st vacuum region of the second bonding chuck may be convexly deformed in a downward direction. At this time, the outer region of the second substrate facing the 2_2nd vacuum region may be fixed to the second bonding chuck.

In one embodiment, the second substrate is pressed by the pressurizer of the substrate bonding apparatus so that the second substrate may come into contact with the first substrate (S740). The second substrate may be pressurized so that the central region of the second substrate is deformed to become convex downward. Thereafter, the second substrate may contact the first substrate at one contact point. At this time, one contact point becomes the bonding initiation point, and the bonding may start from the one contact point. For example, the bonding initiation point may be the point where the center of the first substrate meets the center of the second substrate.

In one embodiment, after the first substrate and the second substrate are bonded at the bonding initiation point, the bonding region between the first substrate and the second substrate may spread from the bonding initiation point toward the outer region (S750). Here, the 2_2nd vacuum region of the second bonding chuck maintains vacuum pressure, so that the outer region of the second substrate may be fixed to the second bonding chuck.

In one embodiment, as the bonding region spreads, the substrate bonding apparatus may release the vacuum pressure of the 2_2nd vacuum region in the second bonding chuck (S760). As the vacuum pressure in the 2_2nd vacuum region is released, the outer region of the second substrate may come into contact with the outer region of the first substrate. This allows the bonding region to extend to the outer region.

In one embodiment, the bonding between the first substrate and the second substrate may occur spontaneously without the application of any external force. As such, bonding diffusion occurs spontaneously between the first substrate and the second substrate, and the center region, the middle region, the outer region, and the edge region of the first substrate may be bonded with the central region, the middle region, the outer region, and the edge region of the second substrate.

When the bonding between the outer region of the first substrate and the outer region of the second substrate is completed, a bonded substrate, in which the upper surface of the first substrate and the lower surface of the second substrate are bonded to each other, may be formed. Thereafter, the vacuum pressure in the first vacuum region of the first bonding chuck is released, so that the bonded substrate may be unloaded.

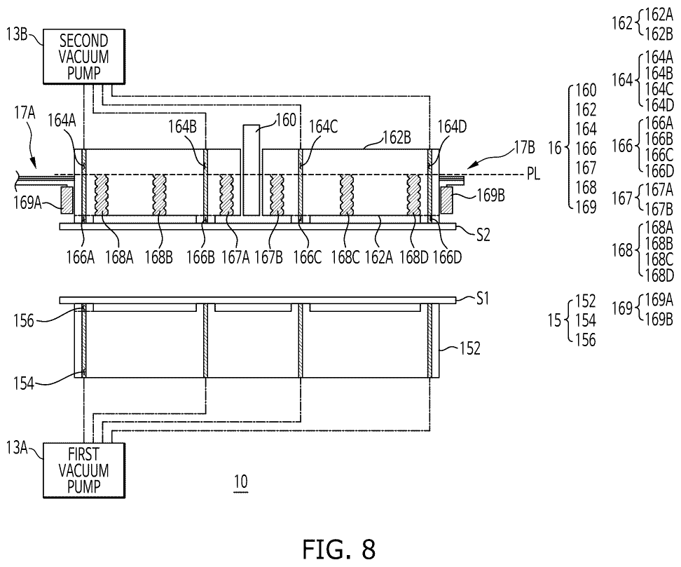

FIGS. 8 to 11 illustrate cross-sectional views that sequentially show an example substrate bonding method using a substrate bonding apparatus 10 according to some embodiments of the present disclosure. FIGS. 8 to 11 illustrate the substrate bonding method described with reference to FIG. 7.

Referring to FIG. 8, the first substrate S1 may be disposed on and fixed to the first bonding chuck 15. For example, the first substrate S1 may be fixed by the vacuum pressure provided by the first vacuum region 156 of the first bonding chuck 15. Here, the vacuum pressure of the first vacuum region 156 may be provided through the first vacuum hole 154 using the first vacuum pump 13A. The second substrate S2 may be disposed and fixed on the second bonding chuck 16. For example, the second substrate S2 may be fixed by the vacuum pressure provided by the second vacuum region 166 of the second bonding chuck 16. Here, the vacuum pressure of the second vacuum region 166 may be provided through the second vacuum hole 164 using the second vacuum pump 13B. Thereafter, the first bonding chuck 15 may be aligned on the second bonding chuck 16 so that the first substrate S1 and the second substrate S2 are aligned. For example, the center of the first substrate S1 and the center of the second substrate S2 may be disposed to face each other.

A substrate bonding method is disclosed in a substrate bonding apparatus 10, and each of a plurality of sensors 167, 168 and 169 included in a second bonding chuck 16 may measure a distance from each of the plurality of sensors 167, 168 and 169 to the upper surface of a second substrate S2. For example, each of the plurality of sensors 167, 168 and 169 may be configured to measure a distance at predetermined intervals in a state in which a substrate bonding method is initiated, thereby generating distance data. Distance data may be transmitted to the controller (e.g., the controller 12 of FIG. 1) through the plurality of sensor lines 17A and 17B.

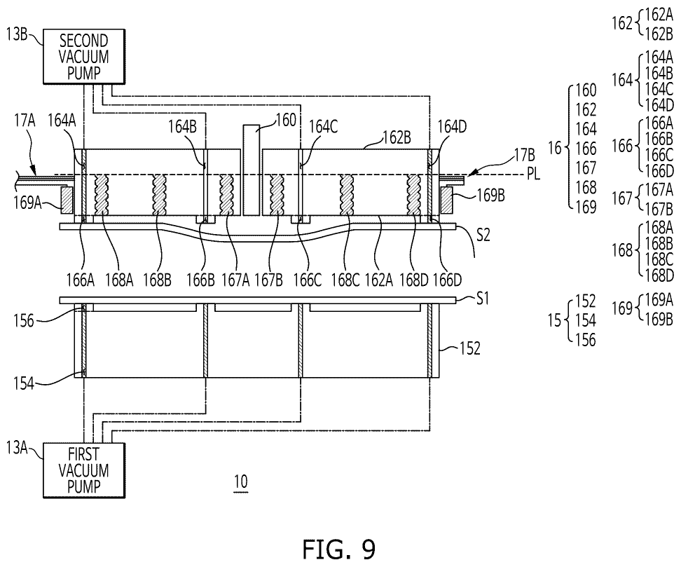

Referring to FIG. 9, the substrate bonding apparatus 10 may release the vacuum pressure of the second_1 vacuum region 166B, 166C in the second bonding chuck 16. Accordingly, the central region of the second substrate S2 facing the s_1st vacuum region 166B and 166C may be convexly deformed in a downward direction. At the same time, the outer region of the second substrate S2 may be fixed to the second bonding chuck 16 by the vacuum pressure of the 2_2nd vacuum region 166D.

The plurality of sensors 167, 168 and 169 may include a plurality of first sensors 167 and 168 and at least one second sensor 169, and the plurality of first sensors 167 and 168 may include a third sensor 167 and a fourth sensor 168. The third sensor 167 adjacent to the inner side of the 2_1st vacuum region 166B and 166C may measure the distance to the central region of the second substrate S2. Accordingly, distance data corresponding to the convexly deformed second substrate S2 may be generated.

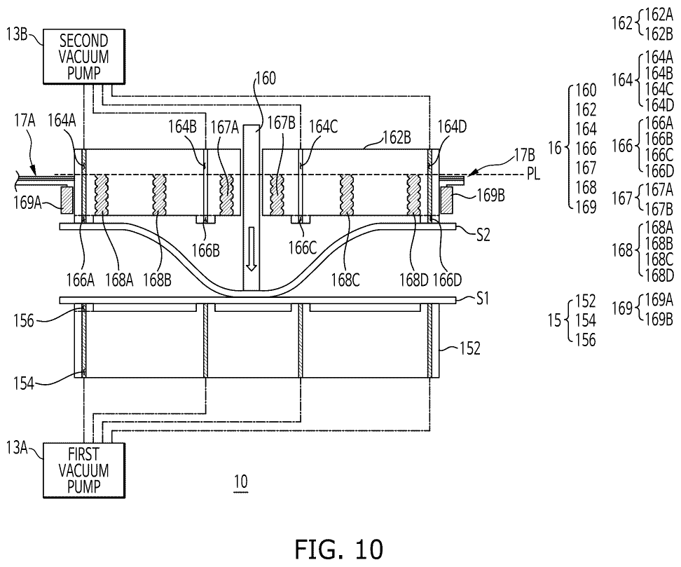

Referring to FIG. 10, the second substrate S2 is pressed by the pressurizer 160 so that the second substrate S2 may come into contact with the first substrate S1. Bonding may be initiated at the bonding initiation point where the second substrate S2 comes into contact with the first substrate S1. The bonding region of the first substrate S1 and the second substrate S2 may be expanded from the bonding initiation point to the outer region. At the same time, the outer region of the second substrate S2 may be fixed to the second bonding chuck 16 by the vacuum pressure of the 2_2nd vacuum region 166D.

The central region and middle region of the second substrate S2 may be deformed to be convex downwards. Here, the central region of the second substrate S2 pressed by the pressurizer 160 may be convex downwards relatively to the middle region. The third sensor 167 adjacent to the inner side of the 2_1st vacuum regions 166B and 166C may measure the distance to the central region of the second substrate S2, and the sixth sensors 168B and 168C disposed at a middle position between the 2_1st vacuum regions 166B and 166C and the 2_2nd vacuum regions 166A and 166D may measure the distance to the middle region of the second substrate S2. Accordingly, distance data corresponding to the second substrate S2 where bonding is initiated may be generated.

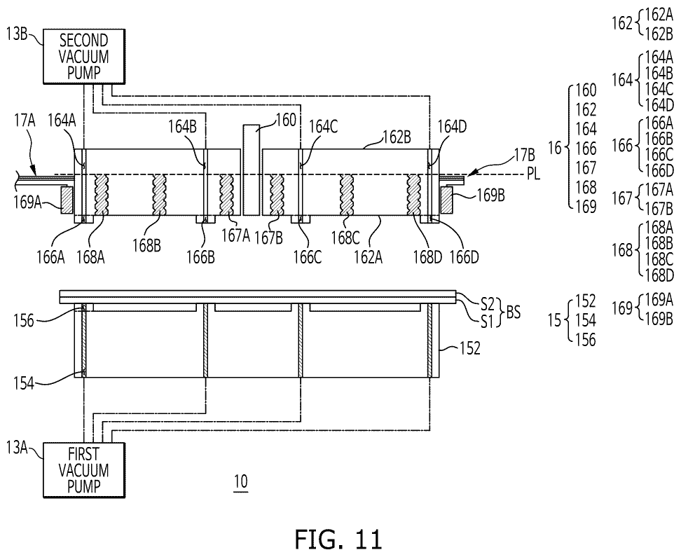

Referring to FIG. 11, the substrate bonding apparatus 10 may release the vacuum pressure of the 2_2nd vacuum region s166A and 166D in the second bonding chuck 16. Specifically, as the vacuum pressure of the second_2 vacuum region 166A, 166D is released, the outer region of the second substrate S2 may fall toward the first substrate S1. As the outer region of the second substrate S2 falls, the outer region of the second substrate S2 may come into contact with the outer region of the first substrate S1. The bonding region may extend from the bonding initiation point to the outer region. Bonding may be completed as the outer region of the second substrate S2 comes into contact with the outer region of the first substrate S1.

The sixth sensors 168B and 168C disposed at an intermediate position between the 2_1st vacuum regions 166B and 166C and the 2_2nd vacuum regions 166A and 166D may measure the distance to the intermediate region of the second substrate S2. The fifth sensors 168A and 168D disposed at the middle position of the second vacuum regions 166A and 166D may measure the distance to the outer region of the second substrate S2. In some embodiments, at least one second sensor 169 may measure the distance to an outer region or edge region of the second substrate S2. Accordingly, distance data corresponding to the second substrate S2 between the start of bonding and the completion of bonding may be generated.

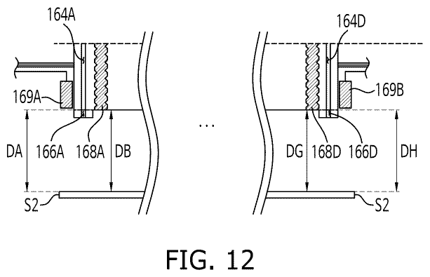

FIG. 12 illustrates a cross-sectional view of an example of a substrate bonding apparatus 10 in which a substrate bonding method according to some embodiments of the present disclosure is performed.

Referring to FIG. 12, in one embodiment, a second substrate S2 may be separated from a second bonding chuck during the substrate bonding method. For example, in a state in which the vacuum pressure of the 2_2nd vacuum regions 166A and 166D is released, the second substrate S2 may be separated from the second bonding chuck. FIG. 12 may show an appearance in which an edge region of a second substrate S2 is separated from a second bonding chuck.

In one embodiment, the 2_1st sensor 169A may measure a first distance DA, which is a distance to the second substrate S2. The second sensor 169B may measure the second distance DH, which is the distance to the second substrate S2. Here, the 2_1st sensor 169A and the 2_2nd sensor 169B may be symmetrical to each other about the center of the 2nd bonding chuck. Similarly, the 5_1st sensor 168A may measure the third distance DB, which is the distance to the second substrate S2. The 5_2nd sensor 168D may measure the fourth distance DG, which is the distance to the second substrate S2. Here, the 5_1st sensor 168A and the 5_2nd sensor 168D may be symmetrical to each other about the center of the second bonding chuck.

In one embodiment, a plurality of first sensors disposed on one surface of the base of the second bonding chuck may be symmetrical with respect to a center of the second bonding chuck. In some embodiments, the 2_1st sensor 169A and the 2_2nd sensor 169B disposed in the outer region of the second bonding chuck may be symmetrical to each other with respect to the center of the second bonding chuck. The controller may compare distance data between symmetrical sensors. Referring to FIG. 12, the first distance DA measured by the 2_1st sensor 169A may be compared with the second distance DH measured by the 2_2nd sensor 169B. In some embodiments, the third distance DB measured by the 5_1st sensor 168A may be compared with the fourth distance DG measured by the 5_2nd sensor 168D.

For example, in a state in which the difference between the first distance DA and the second distance DH exceeds a predetermined threshold, the controller may generate a warning message. Similarly, in a state in which the difference between the third distance DB and the fourth distance DG exceeds a predetermined threshold, the controller may generate a warning message. In some embodiments, in a state in which the difference between the first distance DA and the second distance DH exceeds a predetermined reference value, the vacuum pressure of the vacuum region 166A connected to the 2_1st vacuum hole and the vacuum pressure of the vacuum region 166D connected to the 2_2nd vacuum hole may be adjusted. Similarly, in a state in which the difference between the third distance DB and the fourth distance DG exceeds a predetermined reference value, the vacuum pressure of the vacuum region 166A connected to the 2_1st vacuum hole and the vacuum pressure of the vacuum region 166D connected to the 2_2nd vacuum hole may be adjusted.

In one embodiment, the controller may determine the separation point in time for the edge region of the second substrate S2 based on distance data generated by a plurality of sensors. For example, by releasing the vacuum pressure of the vacuum region 166A connected to the 2_1st vacuum hole, the first edge region of the second substrate S2 may be separated. The controller may determine the point in time when the first edge region of the second substrate S2 is separated based on distance data associated with the 2_1st sensor 169A and/or the 5_1st sensor 168A. Similarly, the second edge region of the second substrate S2 may be separated by releasing the vacuum pressure of the vacuum region 166D connected to the 2_2nd vacuum hole. The controller may determine the point in time when the second edge region of the second substrate S2 is separated based on distance data associated with the 2_2nd sensor 169B and/or the 5_2nd sensor 168D. Here, the first edge region and the second edge region may be symmetrical with respect to the center of the second bonding chuck.

In some embodiments, the controller may adjust the vacuum pressure of the vacuum region 166A connected to the 2_1st vacuum hole and the vacuum pressure of the vacuum region 166D connected to the 2_2nd vacuum hole, based on the separation time point of the first edge region and the separation time point of the second edge region. For example, in a state in which the separation time point of the first edge region is earlier than the separation time point of the second edge region, the controller may delay the vacuum pressure release time of the vacuum region 166A connected to the 2_1st vacuum hole. In this way, the separation time point of the second substrate S2 may be accurately detected using the first sensor disposed on one surface of the second bonding chuck and/or the second sensor disposed on the outer region of the second bonding chuck.

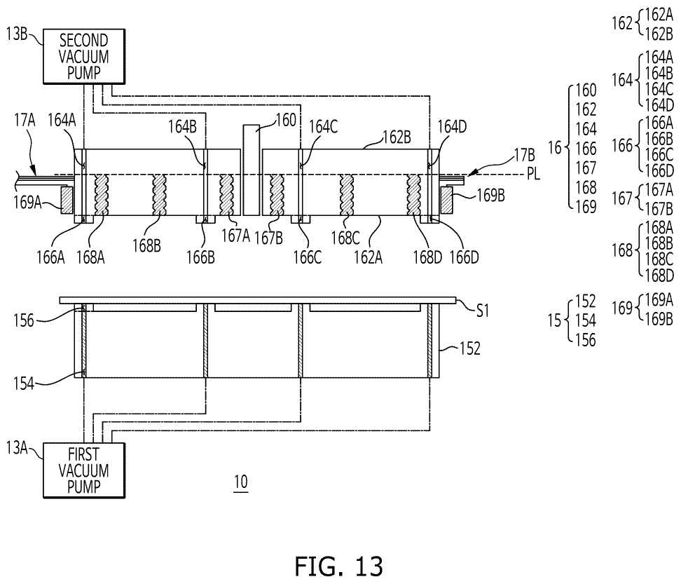

FIG. 13 illustrates a cross-sectional view of an example of a substrate bonding apparatus according to some embodiments of the present disclosure. The substrate bonding apparatus illustrated in FIG. 13 may be substantially the same as the substrate bonding apparatus 10 of FIG. 1 except that a second substrate S2 is disposed therein.

Referring to FIG. 13, the first substrate S1 may be disposed on the upper surface of the first bonding chuck 15. The first substrate S1 may be fixed to the first bonding chuck 15 by vacuum pressure provided through the first vacuum region 156. Meanwhile, the second substrate S2 may be absent on the lower surface of the second bonding chuck 16.

In one embodiment, the plurality of sensors 167, 168 and 169 may measure the distance from each of the plurality of sensors to the upper surface of the first substrate S1. For example, at least one second sensor 169 may measure the distance between at least one second sensor 169 and an edge region of the first substrate S1. The third sensor 167 may measure the distance between the third sensor 167 and the central region of the first substrate S1. The fifth sensors 168A and 168D may measure the distance between the fifth sensors 168A and 168D and the middle region of the first substrate S1. The sixth sensors 168B and 168C may measure the distance between the sixth sensors 168B and 168C and the outer region of the first substrate S1.

As described above, the plurality of sensors 167, 168 and 169 generate distance data for the first substrate S1, and the controller may determine the alignment status of the first substrate S1 based on the distance data. For example, the controller may determine the alignment status in the vertical direction (e.g., the z-axis direction) of the first substrate S1 based on the distance data. In some embodiments, the controller may determine whether there is a foreign substance on the upper surface of the first substrate S1 based on the distance data.

What is claimed is:

1. An apparatus for bonding a substrate, the apparatus comprising:
a bonding chuck comprising a base having the substrate on one surface;
at least one vacuum region, on one surface of the bonding chuck, configured to provide a vacuum pressure for vacuum-absorbing the substrate;
a plurality of first sensors on the one surface of the base; and
at least one second sensor on an outer region of the base,
wherein the plurality of first sensors are configured to measure a first distance from the plurality of first sensors to one surface of the substrate, and
wherein the at least one second sensor is configured to measure a second distance from the at least one second sensor to one surface of the substrate.

2. The apparatus of claim 1, wherein the at least one second sensor is mounted on an outer surface of the base.

3. The apparatus of claim 1, wherein the at least one second sensor is mounted on a plate supporting the bonding chuck.

4. The apparatus of claim 1, wherein the one surface of the bonding chuck is divided by a plurality of straight lines passing through a center of the bonding chuck, and
wherein one first sensor of the plurality of first sensors and the at least one second sensor are disposed along each of the plurality of straight lines.

5. The apparatus of claim 4, wherein the at least one vacuum region comprises:
a first vacuum region on the one surface of the bonding chuck; and
a second vacuum region further from the center of the bonding chuck than the first vacuum region on the one surface of the bonding chuck, and
wherein the plurality of first sensors are installed on at least one of:
a first position adjacent to an inner side of the first vacuum region, or
a second position between the first vacuum region and the second vacuum region.

6. The apparatus of claim 4, wherein the one surface of the bonding chuck is divided into eight regions by the plurality of straight lines, and
wherein an angle between two adjacent straight lines among the plurality of straight lines is equal to or is similar to 45 degrees.

7. The apparatus of claim 1, wherein the base of the bonding chuck comprises:
a first base on which the substrate is disposed; and
a second base on the first base, and
wherein the first base and the second base are detachable.

8. The apparatus of claim 7, wherein the plurality of first sensors are installed on the first base.

9. The apparatus of claim 8, wherein the first base comprises a plurality of sensor insertion holes penetrating the first base, and
wherein each of the plurality of first sensors is inserted and installed into each of the plurality of sensor insertion holes.

10. The apparatus of claim 9, wherein one first sensor of the plurality of first sensors comprises a screw structure and is screw-fastened to one sensor insertion hole of the plurality of sensor insertion holes.

11. The apparatus of claim 1, further comprising a plurality of sensor lines for connecting the plurality of first sensors to a controller outside the bonding chuck,
wherein the plurality of sensor lines penetrate a side surface of the bonding chuck to be connected to the controller.

12. The apparatus of claim 11, wherein the base of the bonding chuck comprises:
a first base on which the substrate is disposed; and
a second base on the first base, and
wherein the first base comprises at least one mounting groove for mounting the plurality of sensor lines extending from one first sensor of the plurality of first sensors and exiting through the side surface of the bonding chuck.

13. The apparatus of claim 1, further comprising a controller configured to control at least one of: the plurality of first sensors or the at least one second sensor.

14. The apparatus of claim 13, wherein the controller is further configured to control the vacuum pressure to the at least one vacuum region, based on distance data received from the plurality of first sensors and the at least one second sensor.

15. The apparatus of claim 14, further comprising a pressurizer configured to press the substrate in a vertical direction of the substrate,
wherein the controller is further configured to adjust a pressure applied by the pressurizer to the substrate, based on the distance data received from the plurality of first sensors and the at least one second sensor.

16. The apparatus of claim 13, wherein the controller is further configured to operate to generate a warning message in a state in which the distance data received from the plurality of first sensors and the at least one second sensor deviates from a predetermined reference value.

17. An apparatus for bonding a substrate, the apparatus comprising:
a first bonding chuck comprising a base having a first substrate on a lower surface;
a second bonding chuck having a second substrate on an upper surface;
at least one first vacuum region, on the lower surface of the first bonding chuck, configured to provide a vacuum pressure for vacuum-absorbing the first substrate;
a plurality of first sensors on the lower surface of the base of the first bonding chuck; and
at least one second sensor on an outer region of the base of the first bonding chuck,
wherein the plurality of first sensors are configured to measure a first distance from the plurality of first sensors to one surface of the first substrate, and
wherein the at least one second sensor is configured to measure a second distance from the at least one second sensor to one surface of the first substrate.

18. The apparatus of claim 17, wherein in a state in which the first substrate is absent on the lower surface of the base of the first bonding chuck, each of the plurality of first sensors and the at least one second sensor are configured to measure a third distance from each of the plurality of first sensors and the at least one second sensor to one surface of the second substrate on the second bonding chuck.

19. The apparatus of claim 17, wherein the second bonding chuck is configured to provide the vacuum pressure for vacuum-absorbing the second substrate, and comprises at least one second vacuum region on the upper surface of the second bonding chuck.

20. An apparatus for bonding a substrate, the apparatus comprising:
a first bonding chuck comprising a base having a first substrate on a lower surface;
a second bonding chuck having a second substrate on an upper surface;
at least one vacuum region configured to provide vacuum pressure for vacuum-absorbing the first substrate, and to penetrate the first bonding chuck;
a plurality of first sensors on the lower surface of the base of the first bonding chuck;
at least one second sensor on an outer region of the base of the first bonding chuck; and
a plurality of sensor lines for connecting the plurality of first sensors to a controller outside the first bonding chuck,
wherein the plurality of first sensors are configured to measure a first distance from the plurality of first sensors to one surface of the first substrate,
wherein the at least one second sensor is configured to measure a second distance from the at least one second sensor to one surface of the first substrate,
wherein the plurality of sensor lines penetrate a side surface of the first bonding chuck to be connected to the controller,
wherein the first bonding chuck is divided by a plurality of straight lines passing through a center of the first bonding chuck, and the plurality of first sensors and the at least one second sensor are disposed along each of the plurality of straight lines,
wherein the at least one vacuum region comprises a first vacuum region on the first bonding chuck, and a second vacuum region further from the center of the first bonding chuck than the first vacuum region, and
wherein the plurality of first sensors are installed on at least one of a first position adjacent to an inner side of the first vacuum region or a second position between the first vacuum region and the second vacuum region.
